(19) United States
(12) Patent Application Publication
(10) Pub. No.: US 2011/0299855 A1
(43) Pub. Date: Dec. 8, 2011

(54) Optical subassembly and manufacturing method thereof

(75) Inventor: Yungliang Huang, DongGuan (CN)

(73) Assignee: SAE Magnetics (H.K.) Ltd., Hong Kong (CN)

(21) Appl. No.: 12/805,654

(22) Filed: Aug. 11, 2010

(30) Foreign Application Priority Data
Jun. 2, 2010 (CN) 201010200995.8

(51) Int. Cl. H04B 10/02; H05K 13/00

(52) U.S. Cl. 398/135; 29/592.1

(57) ABSTRACT

An optical subassembly comprises a transmitter optical subassembly, a receiver optical subassembly, and an electronic assembly connected with the transmitter optical subassembly and the receiver optical subassembly respectively. The transmitter optical subassembly comprises an optical source and an optical source driver driving the optical source; the receiver optical subassembly comprises a photodetector and a control module connecting with the photodetector, and the control module is integrated with a transimpedance amplifier and a limiting amplifier; and the electronic assembly comprises a printed circuit board and a microcontroller formed thereon, and the microcontroller connects with the laser driver and the control module respectively. The present invention can achieve a high integration that is beneficial to the high speed transmission, simplify the layout design of the PCB, and decrease the manufacturing cost.

### FIELD OF THE INVENTION

The present invention relates to the optical communication field, more particularly, to an optical subassembly with high integration and manufacturing method thereof.

### BACKGROUND OF THE INVENTION

In optical communication networks, it is often desirable to use optical components to reduce manufacturing costs. For example, it is common to use optical subassembly to transmit and receive optical signals over optical fibers. A typical optical subassembly comprises various modular components combined in a package assembly. For example, as illustrated in FIG. 1, a typical optical subassembly 600 comprises a transmitter optical subassembly (TOSA) 610, a receiver optical subassembly (ROSA) 620, and an electronic assembly 630 connected with the TOSA 610 and ROSA 620 respectively.

The electronic assembly 630 includes a printed circuit board (PCB) 631, a microcontroller 632, a limiting amplifier 633 and a laser driver 634 mounting on the PCB 631 respectively. The microcontroller 632 services as a dominant function, which communicates with the limiting amplifier 633, the laser driver 634 and the outer application specific integrated circuit ASIC (not shown). Typically, in a MAXIM optical subassembly product, DS 1862 integrated circuit (IC) is commonly used for the microcontroller 632, Max 3992 IC is used for the laser driver 634 and Max 3991 IC is used for the limiting amplifier 633.

The TOSA 610 generally includes an optical source, for example a laser diode (LD) 611 for transmitting optical signals and a monitor photodiode 612 connected with the laser diode 611, which is used to detect that whether the light transmitted by the laser diode 611 satisfies demand. When a digital signal inputs, the laser diode 611 is driven by the laser driver 634 of the electronic assembly 630.

The ROSA 620 generally comprises a photodiode 621 for detecting optical signals and a transimpedance amplifier 622 for converting the optical signals to electrical signals. The limiting amplifier 633 of the electronic assembly 630 connects with the transimpedance amplifier 622, for limiting the current and voltage of the electrical signal.

For preventing the chip circuit from corroding or damaging, the chip must be encapsulated, thus encapsulation and package is an important process of manufacturing the optical subassembly. While the quality of the encapsulation technology will effect the performance of the chip and the design and manufacturing of the PCB connecting with the chip. Nowadays, Surface Mounting Technology (SMT) is a most prevalent technology and process in the electronic packaging field. Known to the people skilled in the art, SMT includes steps of printing, mounting, solidifying, reflow soldering, cleaning, testing and repairing. Therein, Quad Flat No-lead (QFN) package is one of the package types. Generally, the occupied area of the QFN package is large, although it has no lead extended. As described above, for example, the microcontroller DS 1862 IC, the laser driver Max 3992 IC and the limiting amplifier Max 3991 IC are bonded on the PCB using the QFN package form via a standard SMT process.

Due to multiple ICs are formed on the PCB, thus the manufacturing process of such a PCB is quite complicated. In a general way, the layout design of this PCB with multiple ICs mounted thereon at least has six layers, even eight layers sometimes. Therefore a more time and higher cost are needed to be invested, which is beyond the desired range of the manufacturer. Moreover, a plurality of ICs must be made independently, thus the manufacturing material is increased in turn, which increases the manufacturing cost ultimately.

Additionally, as the demand of the high speed transmission and the big bandwidth is desired for achieving, the conventional optical subassembly presents several problems gradually. For example, because the limiting amplifier is mounted on the PCB, and the transimpedance amplifier is formed inside the ROSA, when the transimpedance amplifier of the ROSA communicates with the limiting amplifier, the existent vast distributed capacitances will affect the transmission signal greatly. Furthermore, a severe transmission loss will happen at the same time.

Hence, it is desired to provide an improved optical subassembly and manufacturing method thereof to overcome the above-mentioned drawbacks.

### SUMMARY OF THE INVENTION

One aspect of the present invention is to provide an optical subassembly with high integration which can not only meet the demand of the high speed transmission and big bandwidth for the Optical-Electro and Electro-Optical conversion, but also simplify the PCB design and decrease the manufacturing cost.

Another aspect of the present invention is to provide a manufacturing method of the optical subassembly, which can not only meet the demand of the high speed and big bandwidth for the optical-electrical conversion, but also simplify the PCB design and decrease the manufacturing cost.

To achieve above objectives, an optical subassembly comprises a transmitter optical subassembly, a receiver optical subassembly, and an electronic assembly connected with the transmitter optical subassembly and the receiver optical subassembly respectively. Therein, the transmitter optical subassembly comprises an optical source and an optical source driver driving the optical source; the receiver optical subassembly comprises a photodetector and a control module connecting with the photodetector, and the control module is integrated with a transimpedance amplifier and a limiting amplifier; and the electronic assembly comprises a printed circuit board and a microcontroller formed thereon, and the microcontroller connects with the laser driver and the control module respectively.

In a preferable embodiment, the optical source is a laser diode, and the optical source driver is a laser driver.

In another preferable embodiment, the photodetector is a photodiode.

Preferably, the transmitter optical subassembly further comprises a monitor photodiode to detect the optical source.

Preferably, the control module and the optical source driver are packaged by dice package form respectively.

In another preferable embodiment, the transmitter optical subassembly and the receiver optical subassembly respectively have at least six leads after packaging.

Preferably, the transmitter optical subassembly and receiver optical subassembly connect with the printed circuit board by coupling their leads with a flex cable respectively.

In yet another preferable embodiment, the transmitter optical subassembly and the receiver optical subassembly respectively connect with the printed circuit board via their leads directly.

A method of manufacturing optical subassembly, comprises steps of

(1) packaging a transmitter optical subassembly comprising an optical source and an optical source driver driving the optical source;

(2) integrating a transimpedance amplifier with a limiting amplifier to form a control module;

(3) packaging a receiver optical subassembly comprising a photodetector and a control module connecting with the photodetector;

(4) proving an electronic subassembly comprising a printed circuit board and a microcontroller; and

(5) connecting the transmitter optical subassembly and the receiver optical subassembly to the electronic subassembly.

In a preferable embodiment, the optical source is laser diode, and the optical source driver is laser driver.

In another preferable embodiment, the photodetector is a photodiode.

Preferably, the method of manufacturing optical subassembly further comprises forming a monitor photodiode inside the transmitter optical subassembly to detect the optical source.

Preferably, the method of manufacturing optical subassembly further comprises packaging the laser driver and the control module by dice package form respectively.

In another preferable embodiment, method of manufacturing optical subassembly further comprises mounting the microcontroller on the printed circuit board by Quad Flat No-lead package form.

Preferably, the transmitter optical subassembly and the receiver optical subassembly respectively have at least six leads.

In yet another preferable embodiment, the method of manufacturing optical subassembly further comprises connecting the leads of the transmitter optical subassembly and the receiver optical subassembly to the printed circuit board via a flex cable respectively.

In one more preferable embodiment, the method of manufacturing optical subassembly further comprises respectively connecting the transmitter optical subassembly and the receiver optical subassembly to the printed circuit board via their leads directly.

In comparison with the prior art, the optical subassembly of the present invention integrates with the transimpedance amplifier and the limiting amplifier to form a control module that is embedded into the receiver optical subassembly, and integrates the laser driver into the transmitter optical subassembly. In such a design, the optical subassembly is in a high integration that meets the demand of the high speed transmission and big bandwidth for the Optical-Electro and Electro-Optical conversion. On the other hand, due to there is only one IC of microcontroller mounted on the PCB, thus the layout of the PCB design is simplified, for example, the layers can be decreased to four, which the prior art needs at least six layers. Additionally, as the amount of the chip is decreased, thus the manufacturing cost is cut in turn. Furthermore, the laser driver is provided a good environment to dissipate heat, which is beneficial to the laser performance.

Other aspects, features, and advantages of this invention will become apparent from the following detailed description when taken in conjunction with the accompanying drawings, which are a part of this disclosure and which illustrate, by way of example, principles of this invention.

### BRIEF DESCRIPTION OF THE DRAWINGS

The accompanying drawings facilitate an understanding of the various embodiments of this invention. In such drawings:

FIG. 1 shows the structure of a conventional optical subassembly;

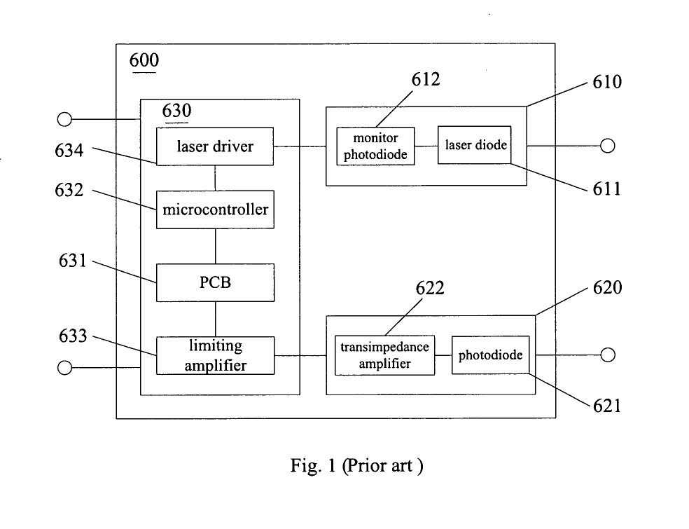

FIG. 2 is a structure block diagram of the optical subassembly according to a first embodiment of the present invention;

FIG. 3 is a structure block diagram of the optical subassembly according to a second embodiment of the present invention;

FIG. 4 is a structure block diagram of the optical subassembly according to a third embodiment of the present invention;

FIG. 5 is a structure block diagram of the optical subassembly according to a fourth embodiment of the present invention; and

FIG. 6 is a flow chart of a method of manufacturing optical subassembly according to one embodiment of the present invention.

### DETAILED DESCRIPTION OF ILLUSTRATED EMBODIMENTS

Various preferred embodiments of the invention will now be described with reference to the figures, wherein like reference numerals designate similar parts throughout the various views. As indicated above, the invention is directed to an optical subassembly which integrates the transimpedance amplifier and the limiting amplifier to form a control module that is embedded into the receiver optical subassembly, and integrates the laser driver into the transmitter optical subassembly. In such a design, the optical subassembly is in a high integration that meets the demand of the high speed and big bandwidth for the Optical-Electro and Electro-Optical conversion. On the other hand, due to there is only one chip of microcontroller mounted on the PCB, thus the layout of the PCB design is simplified, for example, the layers can be decreased to four, which the prior art needs at least six layers. Additionally, as the amount of the chip is decreased, thus the manufacturing cost is cut in turn. Furthermore, the laser driver is provided a good environment to dissipate heat, which is beneficial to the laser performance.

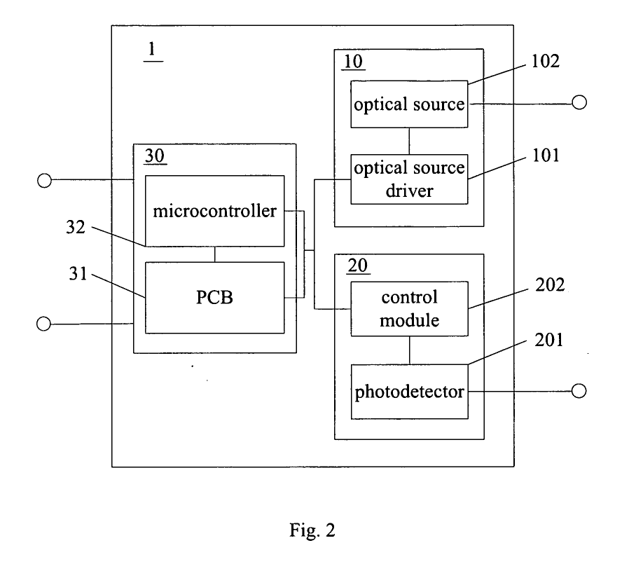

FIG. 2 is a structure block diagram of the optical subassembly according to a first embodiment of the present invention. As shown, the optical subassembly 1 comprises a TOSA 10, a ROSA 20 and an electronic assembly 30. Concretely, the electronic assembly 30 connects with the TOSA 10 and the ROSA 20 respectively.

As shown in FIG. 2, the electronic assembly 30 comprises a PCB 31 and a microcontroller 32 formed thereon. The electronic assembly 30 is an outer controller that is provided and controls the ROSA 20 and TOSA 10. Besides the microcontroller 32, there are many electrical circuit and active elements (not shown) formed on the PCB 31.

As illustrated in FIG. 2, the TOSA 10 comprises an optical source driver 101 and an optical source 102 driven by the optical source driver 101. The TOSA 10 carries out an Electro-Optical conversion process that an electrical signal accesses a signal processor via an encoder, and then a driver actuates an optical source to generate optical signals for sending to the optical fiber.

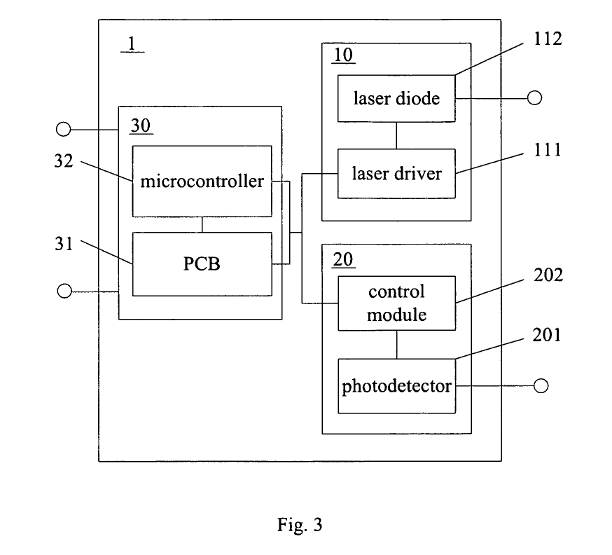

In another embodiment of the present invention, as shown in FIG. 3, the optical source 102 is a laser diode 112, and the optical source driver 101 is a laser driver 111. The laser driver 111 is embedded into the TOSA 10.

The laser diode 112 includes F-P LD (Fabry-Perot Laser Diode), DFBLD (Distributed Feedback Laser Diode) and VCSELD (Vertical Cavity Surface Emitting Laser Diode). Therein the two formers irradiate from the side face of the grain, and the latter irradiates from the surface of the grain. Generally, the F-P LD applies in the high speed transmission system within a medium range, the DFBLD can be applied in the high quality transmission, cable television for example; and the long distance transmission, such as long-distance elecommunication. While VCSELD is a diode having low price, low initial current and stable response to temperature at the same time. The laser diode of the present invention can be any type of the laser diode above, to meet the different demand in the practical application. Moreover, the optical source also can be the light emitting diode (LED).

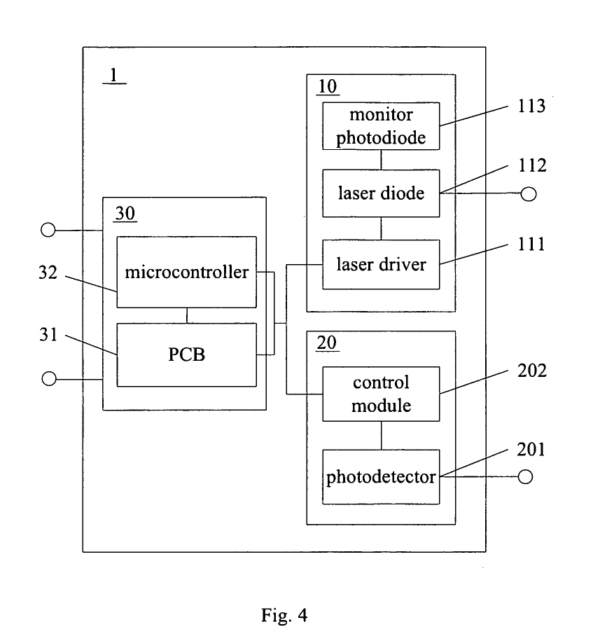

Concretely, with attention now to FIG. 4, in another embodiment of the present invention, the TOSA 10 further includes a monitor photodiode 113 connected to the laser diode 112, which is serviced for detecting that whether the laser transmitting from the laser diode 112 meets the demand.

Preferably, the laser driver 111 of the present invention is integrated into the TOSA 10, thus, the laser driver 111 is packaged by dice package form to make sure the cubage is small enough. Dice package is a package form that integrates multiple chip units and packages them into a chip unit, whose integration density is larger than the QFN package form. Thus, the IC cubage is quite small which meets the practical demand. Moreover, in such a design, the laser driver 111 is provided a good environment to dissipate heat, which is beneficial to the laser performance.

After the TOSA 10 is packaged, the leads of the TOSA 10 are at least six for ensuring a correct communication with PCB 31. Here, one of the connection ways is that, the TOSA 10 connects with the PCB 31 by coupling the six leads with a flex cable (not shown). In another design, the TOSA 10 can connect with the PCB 31 via the leads directly.

When an outer electrical signal inputs, the laser driver 111 starting will actuate the laser diode 112, then the laser diode 112 will change the electrical signal into optical signal, finally the optical signal output is transmitted into an optical fiber. Due to the temperature change and the device aging, the laser will generate a phenomenon that central wavelength excursion, or the optical power is not stable. Therefore, for obtaining a stable optical power output and working temperature, an automatic temperature control circuit and a power control circuit (not shown) are configured commonly.

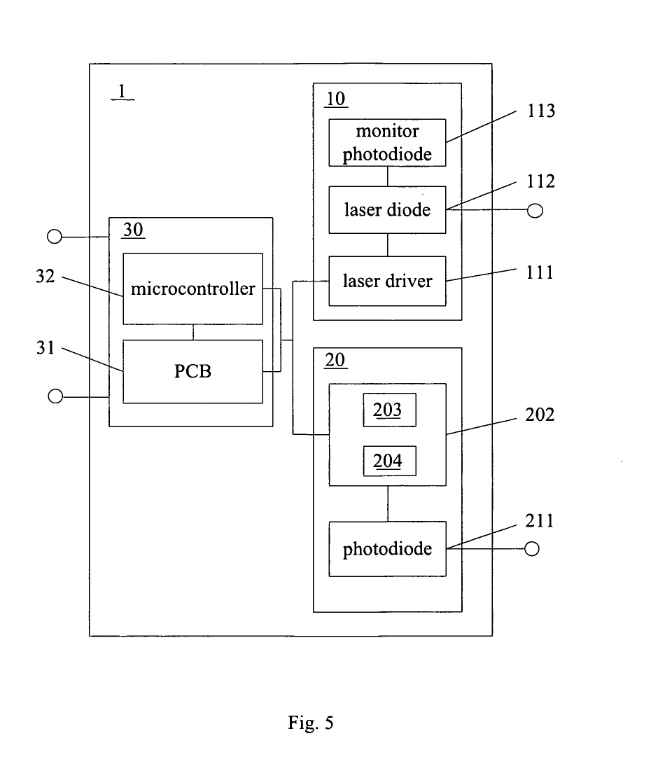

Concretely, with attention to FIGS. 2-4, the ROSA 20 comprises a photodetector 201 and a control module 202 connecting with the photodetector 201. The function of the ROSA 20 is changing the low optical signal to the electrical pulsing signal and amplifying and reverting to original pulsing signal, which is called Optical-Electro conversion process. In one embodiment of the present invention, as shown in FIG. 5, the photodetector 201 is a photodiode 211. Herein, the photodiode 211 can be the PIN Photodiode or Avalanche Photodiode. The control module 202 controls the light transmitted from the photodiode 201. More concretely, the control module 202 is integrated with a transimpedance amplifier 203 and a limiting amplifier 204 at least.

Preferably, the transimpedance amplifier 203 and the limiting amplifier 204 of the present invention are packaged by dice package form. Thus, the chip cubage is decreased greatly and the integration density is increased greatly in turn. Selectively, the other chips of the ROSA 20 also can be integrated into one chip unit by dice package form for meeting a practical demand. Due to the specific integration way, thus the leads of the ROSA 20 after packaging should be at least six for ensuring a correct communication. Here, one of the connection ways is that, the ROSA 20 connects with the PCB 31 by coupling the six leads with a flex cable (not shown). The connection way is suitable for the low speed transmission system that has a lower transmission demand. By contrary, in a high speed transmission design, the ROSA 20 can connect with the PCB 31 via the leads directly. In such a design, as the transimpedance amplifier 203 and the limiting amplifier 204 are integrated together into the ROSA 20 directly, and their leads connect to the PCB 31 directly, thus the transmission loss is decreased, and the effect of the distributed capacitance is decreased in turn, which meet the demand of the high speed transmission and the big bandwidth.

When the optical signal is input, the photodiode 211 detects the optical signal by using the photoelectric effect, which results in the optical signal reverted to Radio Frequency (RF) signal. Actually, it is a decoding process. Then the transimpedance amplifier 203 amplifies the RF signal to meet the demand of the subsequent circuit, and the limiting amplifier 204 will amplify and control the voltage signal not to overload and achieve a best output. As the noise, sensitivity, bandwidth, response speed and the like are the important performance parameters for the ROSA 20, thus the transimpedance amplifier 203 must low noise, high sensitivity, suitable bandwidth, big dynamic range and good temperature stability, which is beneficial to maintain a good performance.

Selectively, for optimizing the voltage signal from the transimpedance amplifier 203, a main amplifier (not shown) can be configured after the transimpedance amplifier 203. Sometimes, an equalizer (not shown) is also contained for overcome the intersymbol interference to carry out an extent judgment. Within the concept of the invention, the main amplifier and equalizer and the like can be integrated into the control module 202.

In comparison with the prior art, the optical subassembly 1 of the present invention integrates the transimpedance amplifier 203 and the limiting amplifier 204 to form a control module 202 that is embedded into the ROSA 20, and integrates the laser driver 211 into the TOSA 10. In such a design, the optical subassembly is in a high integration that meets the demand of the high speed and big bandwidth for the Optical-Electro and Electro-Optical conversion. On the other hand, due to there is only one chip of microcontroller 32 mounted on the PCB 31, thus the layout of the PCB 31 design is simplified, for example, the layers can be decreased to four, which the prior art needs at least six layers. Additionally, as the amount of the chip is decreased, thus the manufacturing cost is cut in turn. Furthermore, the laser driver is provided a good environment to dissipate heat, which is beneficial to the laser performance.

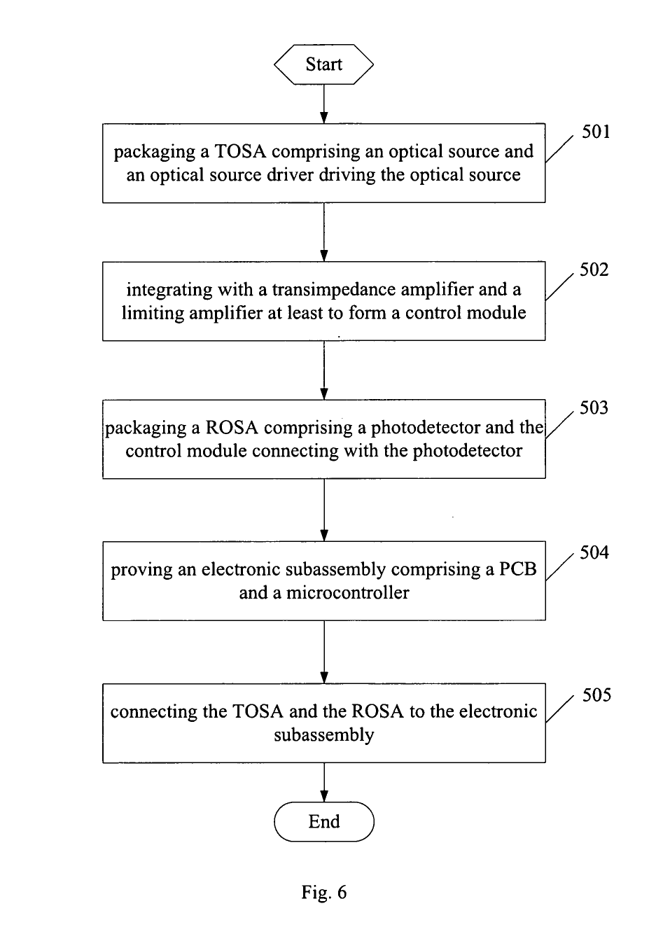

FIG. 6 is a flow chart of a method of manufacturing the optical subassembly according to one embodiment of the present invention. As shown, the steps thereof includes:

Step (501) packaging a TOSA comprising an optical source and an optical source driver driving the optical source;

Step (502) integrating with a transimpedance amplifier and a limiting amplifier at least to form a control module;

Step (503) packaging a ROSA comprising a photodetector and the control module connecting with the photodetector;

Step (504) proving an electronic subassembly comprising a PCB and a microcontroller; and

Step (505) connecting the TOSA and the ROSA to the electronic subassembly.

Concretely, in the step (501), the method further comprises packaging the optical source driver by dice package form. More concretely, the optical source of the present invention is a laser diode, and the optical source driver is a laser driver. As described above, the laser diode can be any type of the laser diode. Additionally, the optical source also can be the LED.

Preferably, the method further comprises forming a monitor photodiode inside the TOSA, which connects with the laser diode to detect the laser quality.

In the step (502), the method further comprises packaging the control module that includes transimpedance amplifier and a limiting amplifier at least by dice package form.

Concretely, the photodetector is a photodiode, and the photodiode can be the PIN Photodiode or Avalanche Photodiode as mentioned above. The control module controls the light transmitted from the photodiode. As the control module is integrated into the ROSA, thus, the integration density is increased which meets the high speed transmission demand nowadays.

In the step (504), the method of the present invention further comprises mounting the microcontroller on the PCB by QFN package form. Besides the microcontroller, there are many electrical circuit and active elements formed on the PCB. Here, as the integration way mentioned above, thus only one chip of the microcontroller is on the PCB. In other words, compared with the prior art, the amount of the chip on the PCB of the present invention is decreased. Thus the layout design of the PCB according to the present invention is very easy and simple which can decrease the manufacturing cost greatly.

Preferably, after the TOSA and ROSA are packaged, the leads of the TOSA and ROSA are at least six for ensuring a correct communication. Here, one of the connection ways is that, the TOSA and ROSA connects with the PCB by coupling the six leads with a flex cable. The connection way is suitable for the low speed transmission that has a lower transmission demand. By contrary, in a high speed transmission design, the TOSA and ROSA can connect with the PCB via the leads directly. In such a design, the transmission loss is decreased, and the effect of the distributed capacitance is decreased in turn, which is beneficial to the high speed transmission.

In comparison with the prior art, the optical subassembly of the present invention integrates the transimpedance amplifier 203 and the limiting amplifier 204 to form a control module 202 that is embedded into the ROSA 20, and integrates the laser driver 211 into the TOSA 10. In such a design, the optical subassembly is in a high integration that meets the demand of the high speed and big bandwidth for the Optical-Electro and Electro-Optical conversion. On the other hand, due to there is only one chip of microcontroller 32 mounted on the PCB 31, thus the layout of the PCB 31 design is simplified, for example, the layers can be decreased to four, which the prior art needs at least six layers. Additionally, as the amount of the chip is decreased, thus the manufacturing cost is cut in turn. Furthermore, the laser driver is provided a good environment to dissipate heat, which is beneficial to the laser performance.

While the invention has been described in connection with what are presently considered to be the most practical and preferred embodiments, it is to be understood that the invention is not to be limited to the disclosed embodiments, but on the contrary, is intended to cover various modifications and equivalent arrangements included within the spirit and scope of the invention.

What is claimed is:

1. An optical subassembly comprising a transmitter optical subassembly, a receiver optical subassembly, and an electronic assembly connected with the transmitter optical subassembly and the receiver optical subassembly respectively; wherein
the transmitter optical subassembly comprising an optical source and an optical source driver driving the optical source;
the receiver optical subassembly comprising a photodetector and a control module connecting with the photodetector, and the control module is integrated with a transimpedance amplifier and a limiting amplifier at least; and
the electronic assembly comprising a printed circuit board and a microcontroller formed thereon, and the microcontroller connects with the optical source driver and the control module respectively.

2. The optical subassembly as claimed in claim 1, wherein the optical source is a laser diode, and the optical source driver is a laser driver.

3. The optical subassembly as claimed in claim 1, wherein the photodetector is a photodiode.

4. The optical subassembly as claimed in claim 1, wherein the transmitter optical subassembly further comprises a monitor photodiode to detect the optical source.

5. The optical subassembly as claimed in claim 1, wherein the control module and the optical source driver are packaged by dice package form respectively.

6. The optical subassembly as claimed in claim 1, wherein the transmitter optical subassembly and the receiver optical subassembly respectively have at least six leads after packaging.

7. The optical subassembly as claimed in claim 6, wherein the transmitter optical subassembly and receiver optical subassembly connect with the printed circuit board by coupling their leads with a flex cable respectively.

8. The optical subassembly as claimed in claim 6, wherein the transmitter optical subassembly and the receiver optical subassembly respectively connect with the printed circuit board via their leads directly.

9. A method of manufacturing optical subassembly, comprising steps of:
(1) packaging a transmitter optical subassembly comprising an optical source and an optical source driver driving the optical source;
(2) integrating with a transimpedance amplifier and a limiting amplifier at least to form a control module;
(3) packaging a receiver optical subassembly comprising a photodetector and the control module connecting with the photodetector;
(4) proving an electronic subassembly comprising a printed circuit board and a microcontroller; and
(5) connecting the transmitter optical subassembly and the receiver optical subassembly to the electronic subassembly respectively.

10. The method of manufacturing optical subassembly as claimed in claim 9, wherein the optical source is laser diode, and the optical source driver is laser driver.

11. The method of manufacturing optical subassembly as claimed in claim 9, wherein the photodetector is a photodiode.

12. The method of manufacturing optical subassembly as claimed in claim 9, wherein further comprises forming a monitor photodiode inside the transmitter optical subassembly.

13. The method of manufacturing optical subassembly as claimed in claim 9, wherein further comprises packaging the optical source driver and the control module by dice package form respectively.

14. The method of manufacturing optical subassembly as claimed in claim 9, wherein further comprises mounting the microcontroller on the printed circuit board by Quad Flat No-lead package form.

15. The method of manufacturing optical subassembly as claimed in claim 9, wherein the transmitter optical subassembly and the receiver optical subassembly respectively have at least six leads.

16. The method of manufacturing optical subassembly as claimed in claim 15, wherein further comprising connecting the leads of the transmitter optical subassembly and the receiver optical subassembly to the printed circuit board via a flex cable respectively.

17. The method of manufacturing optical subassembly as claimed in claim 15, wherein further comprises respectively connecting the transmitter optical subassembly and the receiver optical subassembly to the printed circuit board via their leads directly.
